(19) United States
(12) Patent Application Publication
(10) Pub. No.: US 2026/0140217 A1
(43) Pub. Date: May 21, 2026

(54) METHOD AND SYSTEM FOR MOTION-ROBUST SUPER-RESOLUTION MAGNETIC RESONANCE IMAGING

(71) Applicant: The General Hospital Corporation, Boston, MA (US)

(72) Inventors: Fuyixue Wang, Charlestown, MA (US); Zijing Dong, Charlestown, MA (US); Jonathan Polimeni, Cambridge, MA (US); Lawrence L. Wald, Cambridge, MA (US)

(21) Appl. No.: 19/119,707

(22) PCT Filed: Oct. 12, 2023
(86) PCT No.: PCT/US2023/076639

§ 371 Date: Apr. 9, 2025

Related U.S. Application Data
(60) Provisional application No. 63/415,573, filed on Oct. 12, 2022.

(51) Int. Cl. G01R 33/565; G01R 33/483; G01R 33/56; G01R 33/561

(52) U.S. Cl. CPC G01R 33/56509; G01R 33/4835; G01R 33/5608; G01R 33/5616

(57) ABSTRACT

The present disclosure provides a method for generating MRI images of a subject. The method includes accessing MRI images of the subject that have a first resolution, where each of the MRI images was acquired with a selected sampling pattern. The method further includes estimating motion between the MRI images to determine a motion transformation that corresponds to motion of the subject between the MRI images. The method further includes applying a model-based super-resolution reconstruction to the MRI images. The reconstruction accounts for the motion transformation and generates an image of the subject within the image volume that has a second resolution greater than the first resolution.

### CROSS-REFERENCE TO RELATED APPLICATIONS

This application is based on, claims priority to, and incorporates herein by reference for all purposes, U.S. Provisional Patent Application No. 63/415,573 filed on Oct. 12, 2022.

### STATEMENT REGARDING FEDERALLY SPONSORED RESEARCH

This invention was made with government support under grant number 5P41EB030006-03 awarded by the National Institutes of Health. The government has certain rights in the invention.

### BACKGROUND

Increasing the spatial resolution of magnetic resonance imaging (MRI) is challenging due to the inherent low SNR of a smaller voxel. Many efforts have been made to improve the SNR efficiency for high-resolution imaging. For example, several emerging methods have been developed using slab encoding, including simultaneous multi-slab imaging and simultaneous multislice imaging with generalized slice dithered enhanced resolution (SMS-gSlider). Such methods are often combined with parallel imaging to mitigate distortions and have shown promising results for submillimeter diffusion MRI. These techniques still suffer from several limitations, including distortion and blurring, spin-history striping artifacts, the need for navigator acquisition, and high SAR-deposition from specialized RF pulses.

Another promising approach to increase SNR efficiency is super-resolution acquisition and reconstruction, which can avoid extra SAR-deposition and spin-history striping artifacts. Super-resolution techniques achieve higher SNR efficiency by acquiring multiple thick-slab or low-resolution volumes with different positions, orientations or encodings, from which a high-resolution volume with higher SNR can be recovered through a super-resolution reconstruction. However, the need to acquire multiple low-resolution volumes makes super-resolution techniques highly susceptible to motion and field changes (e.g., eddy currents), which could cause position and geometric distortion differences between the low-resolution volumes. These inconsistencies can lead to severe image artifacts and blurring in the final reconstructed high-resolution image, limiting its ability to achieve ultra-high resolution.

Thus, a need exists to provide clinicians with the imaging data desired, such as high resolution and high signal-to-noise ratios, but without the shortcomings of existing attempts.

### SUMMARY OF THE DISCLOSURE

The present disclosure addresses the aforementioned drawbacks by providing a system and method for motion-robust super-resolution magnetic resonance imaging (MRI).

The present disclosure provides an MRI system that includes a magnet system that generates a static polarizing magnetic field (B₀) over at least a portion of a subject arranged in the MRI system. The system further includes a plurality of gradient coils that apply magnetic gradients to the polarizing magnetic field and a radiofrequency (RF) system that applies an excitation field to the subject. The system further includes a computer system that is programmed to carry out steps. The steps include controlling the gradient coils and RF system to acquire a first set of imaging data from the subject. The first set of imaging data has a first sampling resolution achieved using a first spatial encoding and first sampling pattern. The steps further include repeatedly controlling the gradient coils and RF system to acquire another set of imaging data from the subject, which has another spatial encoding that differs from a preceding spatial encoding and another sampling pattern. The repeated image acquisition generates a plurality of sets of imaging data that have respective sampling patterns. The steps further include estimating motion between the plurality of sets of imaging data to determine a motion transformation that represents motion of the subject between the plurality of sets of imaging data. The steps also include using the motion transformation to perform a model-based super-resolution reconstruction of the plurality of sets of imaging data and generate an image of the subject that has a resolution greater than the first resolution.

The present disclosure also provides a method for generating MRI images of a subject. The method includes accessing MRI images of the subject that have a first resolution, where each of the MRI images was acquired with a selected sampling pattern. The method further includes estimating motion between the MRI images to determine a motion transformation that corresponds to motion of the subject between the MRI images. The method further includes applying a model-based super-resolution reconstruction to the MRI images. The reconstruction accounts for the motion transformation and generates an image of the subject within the image volume that has a second resolution greater than the first resolution.

These are but a few, non-limiting examples of aspects of the present disclosures. Other features, aspects and implementation details will be described hereinafter.

### BRIEF DESCRIPTION OF THE DRAWINGS

The patent or patent application file contains at least one drawing in color. Copies of this patent or patent application publication with color drawings will be provided by the Office upon request and payment of the necessary fee.

Various objects, features, and advantages of the disclosed subject matter can be more fully appreciated with reference to the following detailed description of the disclosed subject matter when considered in connection with the following drawings, in which like reference numerals identify like elements.

The figures provided were chosen to demonstrate the efficacy of the invention, which can be seen in the improved resolution of the images reconstructed with the described methods. Thus, the quality of some of the drawings is poor or below the level required, as the raw data were acquired with lower resolution than that of the resulting reconstructed images. Such images are labeled accordingly.

FIG. 1A is a flow chart that illustrates an example process for producing high-resolution images in accordance with some aspects of the present disclosure.

FIG. 1B is a flow chart that illustrates an example process for acquiring MRI data in accordance with some aspects of the present disclosure.

FIG. 1C shows an example of sampling schemes in accordance that may be used for data acquisition in accordance with the present disclosure.

FIG. 2A illustrates an example pulse sequence diagram that can be used to acquire MRI data in accordance with some aspects of the present disclosure.

FIG. 2B shows an example sampling pattern of hybrid k_{y}-t space, which may be used in accordance with some aspects of the present disclosure.

FIG. 3 illustrates an example super-resolution acquisition strategy for diffusion MRI that may be used in accordance with some aspects of the present disclosure.

FIG. 4 provides example results of images generated using the methods described in the present disclosure.

FIG. 5 provides another example of three orthogonal images generated with the methods described in the present disclosure.

FIG. 6 shows an example of images reconstructed with the methods described in the present disclosure compared to a conventional method.

FIG. 7A provides an example of a tradeoff of point spread function error and SNR used to tune a regularization in accordance with some aspects of the present disclosure.

FIG. 7B provides an example of motion-robust images generated using the methods described in the present disclosure.

FIG. 7C shows image results from another example implementation of the methods described in the present disclosure.

FIG. 7D shows a comparison of super-resolution images with standard reference images used to assess residual distortion.

FIG. 8 shows example diffusion-weighted images and T₂* maps generated using the methods described in the present disclosure.

FIG. 9A shows example fractional anisotropy maps and diffusion tensors generated using the methods described in the present disclosure.

FIG. 9B shows example images generated using the methods described in the present disclosure on a 7 T MRI system.

FIG. 10 shows example images for microstructure imaging generated using the methods described in the present disclosure.

FIG. 11 is a block diagram of an example magnetic resonance imaging (“MRI”) system that can implement the methods described in the present disclosure.

FIG. 12 is a block diagram of an example super-resolution system that can implement the methods of the present disclosure.

FIG. 13 is a block diagram of example components that can implement the system of FIG. 12.

### DETAILED DESCRIPTION

Before any aspects of the present disclosure are explained in detail, it is to be understood that the invention is not limited in its application to the details of construction and the arrangement of components set forth in the following description or illustrated in the following drawings. The invention is capable of other embodiments and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings. Further, “connected” and “coupled” are not restricted to physical or mechanical connections or couplings.

The present disclosure describes a system and method to enable motion-robust super-resolution magnetic resonance imaging (MRI) through design of MRI acquisition and reconstruction. The systems and methods provided herein can significantly improve the spatial resolution of MRI volumes with high SNR gain, while providing high reconstruction accuracy and robustness to motion and field changes. The system and method can provide high quality images with mitigated or minimized artifacts, including artifacts related to motion or field changes; blurring and distortion; and spin-history artifacts. As a non-limiting example, the system and method may provide in-vivo high-resolution and mesoscale diffusion MRI (dMRI) of the brain. As another non-limiting example, the system and method may provide SNR efficient microstructure imaging of the brain.

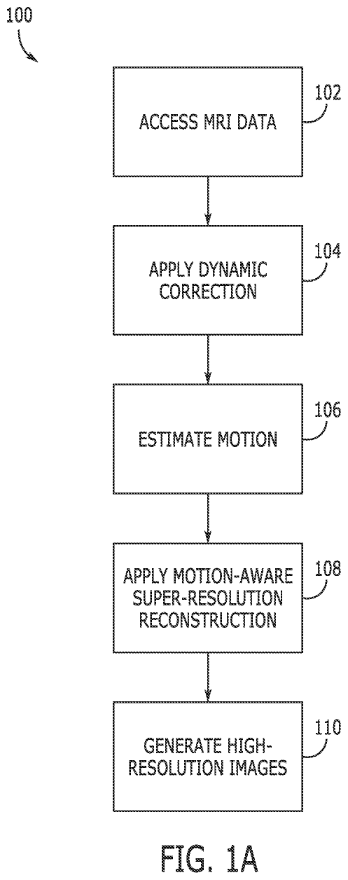

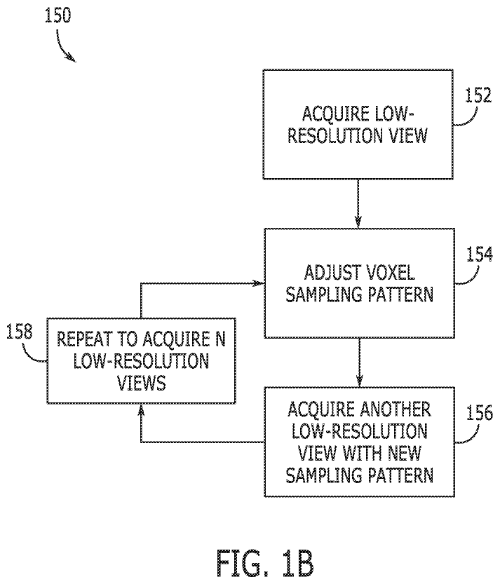

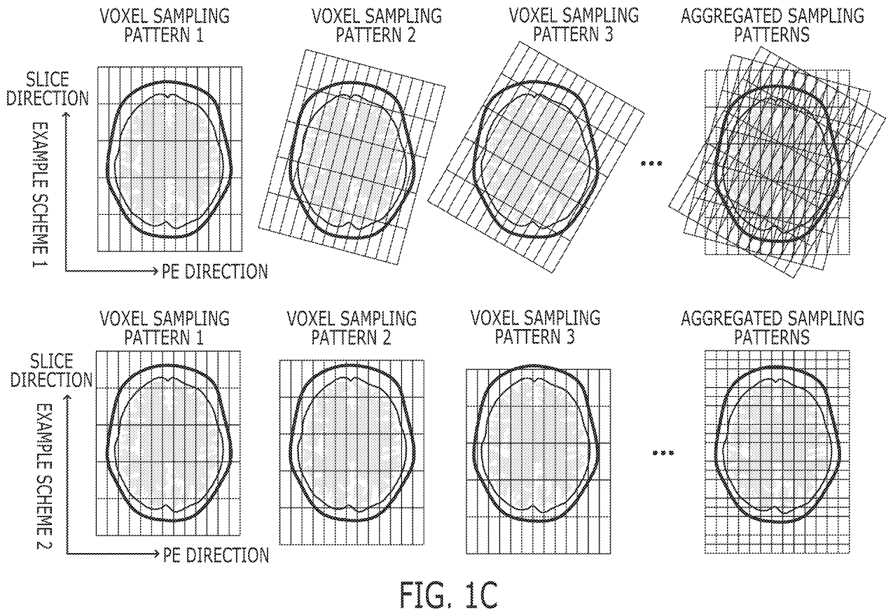

Referring to FIG. 1A, a flowchart is provided that illustrates an example process 100 that may be used to produce super-resolution MRI in accordance with some aspects of the present disclosure. In general, the process 100 uses a motion-aware model-based super-resolution reconstruction to improve the slice resolution of MRI data acquired with a variety of spatial encodings and low slice resolution.

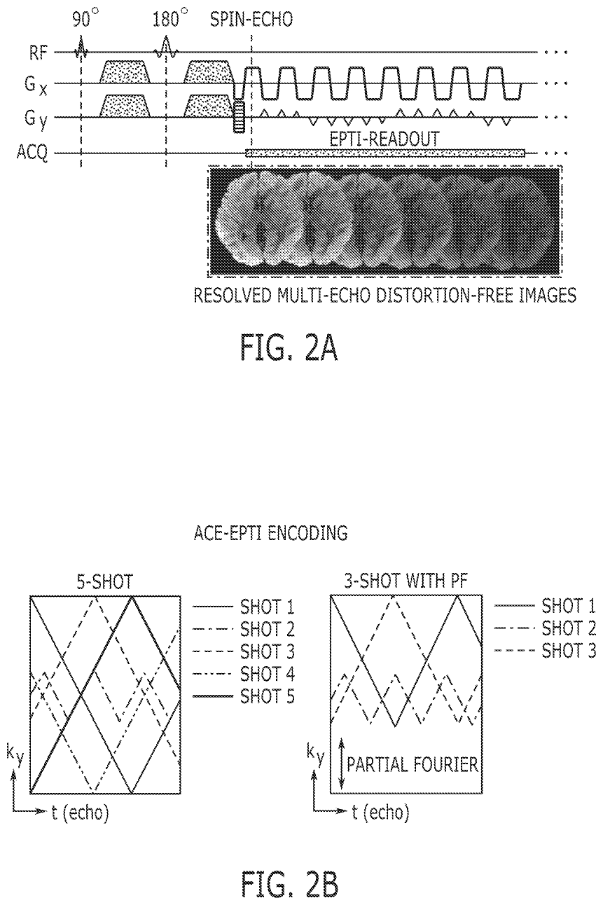

MRI data is acquired or accessed, as indicated in block 102. The MRI data can be acquired by an MRI system (such as will be described with respect to FIGS. 1B, 1C, 2A, and 2B) or accessed from memory by a computer system. The data may be acquired with a desired contrast based on the application. For example, the MRI data may include diffusion MRI data, functional MRI data, anatomical scans, quantitative MRI data, or other types of MRI acquisitions. The MRI data can include multiple 2D images or 3D volumes with low resolution or encoded voxels, which may be referred to as acquired resolution or sampling resolution. For example, the data may particularly have low resolution in the slice direction. As a non-limiting example, the acquired volumes may have an in-plane resolution of 0.5 mm×0.5 mm and 4 mm slice thickness, or less. The MRI data is acquired with a variety of parameters and/or spatial encodings to provide multiple views of a common imaging volume or volume of interest (VOI). For example, the variable spatial parameters may include the prescribed positions, orientations, or spatial encodings of the acquired slices or voxels. The parameters or spatial encodings may be achieved by using different RF pulses, different gradient waveforms, coils, subject position, or a combination thereof. The variable parameters may also include various contrast encoding, such as a magnitude or direction of diffusion weighting. The data acquisition order may also be chosen to reduce or eliminate spin-history artifacts. For example, all of the dynamic volumes (e.g., diffusion direction, diffusion weight, functional timepoint, or other contrast) may be acquired for each individual spatial encoding (e.g., slice orientation or angle) before beginning another spatial encoding.

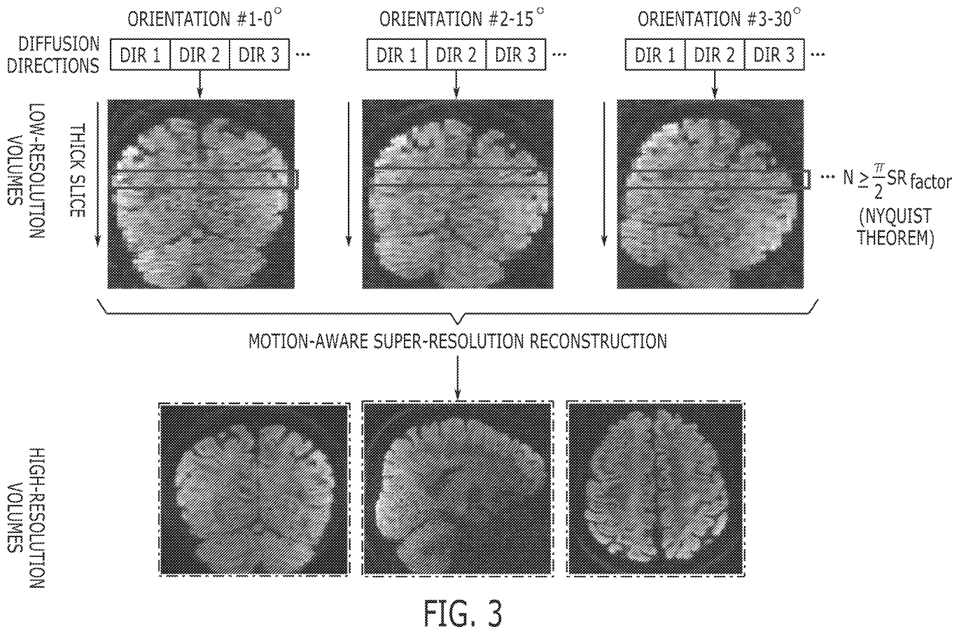

As a non-limiting example, the MRI data may include dMRI data of the brain acquired using thick-slice volumes of different slice angles. The data may be acquired using a distortion-free or reduced-distortion method. As one non-limiting example, reduced-distortion imaging may include echo-planar time-resolved imaging (EPTI) as described in U.S. Pat. No. 11,022,665, which is incorporated herein by reference in its entirety. Reduced-distortion imaging may also include methods such as accelerated echo-train shifted EPTI (ACE-EPTI), multi-shot echo planar imaging (EPI), segmented EPI, parallel imaging, other sampling strategies (e.g., non-cartesian sampling), or other sequences (e.g., turbo spin echo (TSE) sequences, Gradient Echo (GRE), blip-up and blip-down EPI sequences, and so on). In general, a reduced-distortion method refers to an acquisition or processing method that has reduced distortion as compared to acquiring the same k-space sampling with standard EPI, and distortion-free method refers to an acquisition or processing method that eliminates at least 90% of the image distortion. To reduce spin-history artifacts, all of the diffusion-weighted or other contrast volumes (e.g., of various b-values and diffusion directions) can be acquired for each slice orientation prior to switching to a new slice orientation, as illustrated in FIG. 3. Other super-resolution schemes and other acquisition orderings of the super-resolution encoded volumes and contrast encoding volumes (e.g., diffusion weighted volumes) may also be used.

FIG. 1B provides an example process 150 that may be used in block 102 to acquire MRI data. A first view of the imaging VOI is acquired in block 152. The first view may have a prescribed spatial encoding to sample the VOI with an initial voxel sampling pattern. The MRI system (e.g., magnetic spatial gradients, radiofrequency (RF) system) can be controlled to acquire the data according to the spatial encoding. The spatial encoding can be adjusted in block 154 in order to sample the VOI with a new voxel sampling pattern, providing a new view of the object within the VOI in block 156. This process can be repeated N times in block 158 to provide multiple views of the VOI. That is, the VOI will be sampled with multiple different voxel sampling patterns. In general, the data acquired in process 150 is sampled with a low-resolution in comparison to the reconstructed image, as will be described in further detail below.

FIG. 1C provides two non-limiting example sampling schemes that may be used with process 150. In the first example scheme, the voxel sampling pattern is rotated with each acquisition to provide a rotated view of the VOI. For example, the rotation can be described by some fixed or variable angle of rotation between acquisitions. The rotation can be applied along any desired axis. In some implementations the rotation is applied around an axis orthogonal to the slice direction, such as the phase encoding (PE) or readout (RO) direction (as shown). In the second example scheme, the voxel sampling pattern is shifted along the low-resolution dimension (e.g., slice direction). The sampling pattern may also be simultaneously shifted in other directions (e.g., slice direction and PE direction). In general, the distance of shift between acquisitions is less than the distance of the voxel in the given dimension. For example, the voxel sampling pattern may be shifted by 1 mm in the slice dimension while acquiring 4 mm slices. The total number of views (N) may be determined by the Nyquist sampling theorem according to the desired resolution gain. Each of the acquisitions may have a sampling resolution or acquired resolution that is lower (i.e., larger voxel size) than the final reconstructed resolution, as will be described further below. The resolution may be lower in one (e.g., slice) or more dimensions. The resolution of each view may be equal or may vary with each acquisition. While FIG. 1C provides two example sampling schemes, other sampling schemes may be used. For example, low-resolution images may be acquired in two or three orthogonal views or encoded using different RF pulses, different gradient waveforms, coils, subject positions, or a combination thereof. In general, the sampling scheme provides multiple views with varying voxel sampling patterns of at least a common volume or VOI. Acceleration may be used to sample fewer or only a portion of the views or voxel sampling patterns to reduce the scan time. Simultaneous multi-slice (“SMS”) or simultaneous multi-slab can be implemented together with the super-resolution acquisition to further boost the SNR efficiency. 2D or 3D acquisition may be used to sample the volumes.

Referring again to FIG. 1A, block 102 may also include image reconstruction and other data processing. For example, accessing MRI data may include reconstructing image data from k-space data, which may include Fourier transforms. The reconstruction may also include data processing steps, such as filtering, parallel imaging reconstruction, time-resolved reconstruction, compressed sensing reconstruction, low-rank reconstruction, subspace reconstruction, artifact correction, noise reduction, or other data processing methods.

Dynamic correction can optionally be applied in block 104. The dynamic correction may include distortion correction (e.g., Functional Magnetic Resonance Imaging of the Brain (FMRIB) Software Library (FSL) topup, Diffeomorphic Registration for Blip-Up blip-Down Diffusion Imaging (DR-BUDDI), Statistical Parametric Mapping (SPM) distortion correction, Analysis of Functional Neuro-Images (AFNI) distortion correction, or others) and eddy current correction (e.g., FSL eddy). The distortion correction may also include applying a non-rigid transformation to align the low-resolution images. For example, an optimization may be performed to determine a transformation matrix to reduce a cost function. The cost function may be based on mutual information, normalized mutual information, cross-correlation, a difference in image magnitude or sum of squared image intensity, a uniformity in a ratio of the images, or other image registration cost functions. Field map-based correction or image-based correction through a modified acquisition such as reversed phase encoding can also be used to correct for distortion to improve the performance of the super-resolution system.

Motion estimation may be performed in block 106 to determine a motion transformation between each of the low-resolution volumes. As a non-limiting example, motion estimation may include navigated or self-navigated motion correction. For example, the acquired low-resolution volumes can be used as input to estimate the motion between them using a self-navigated method without the need for an extra navigator image acquisition in this case. Respiratory motion may be estimated using a measurement of the respiratory cycle, such as using a respiratory bellow or from the imaging data. As another non-limiting example, motion estimation may be applied using rigid or non-rigid image registration. For example, a cost function may be defined and reduced or minimized to estimate motion. The cost function may be based on mutual information, normalized mutual information, cross-correlation, a difference in image magnitude or sum of squared image intensity, a uniformity in a ratio of the images, or other image registration cost functions. The motion estimation can be represented by a transformation matrix or a motion transform model, which can be applied to the low-resolution images to align the images. Intra-volume or inter-shot motion estimation can also be performed by estimating and modeling the relative motion between the acquired subset of slices or between different shots.

A motion-aware super-resolution reconstruction is applied, as indicated in block 108. The super-resolution reconstruction can be applied in the image domain, k-space domain, or hybrid domain (e.g., kₓ-k_{y}-z) to generate an image that has higher resolution than that of the acquired images. The reconstruction can be performed using either magnitude, real-value, or complex data (e.g., real value diffusion to reduce noise floor). The reconstruction can be applied independently for one set of low resolution or encoded volumes to generate one high resolution volume. Additionally or alternatively, the reconstruction can be applied jointly across multiple sets of low resolution or encoded volumes (e.g., across different repetitions or diffusion directions) to obtain one or multiple high resolution volumes. Denoising methods such as PCA-based methods can be applied after or before the super-resolution reconstruction to reduce noise.

The reconstruction can include a model-based reconstruction in which a cost function is reduced or minimized. The cost function can include a difference between the target high-resolution reconstructed image and the transformed and motion-corrected low-resolution acquired images. The cost function may also include a regularization term. For example, the regularization may include a Tikhonov regularization, total variation (TV), Huber loss, non-local mean method, gradient guidance, wavelet transform, low-rank/locally low-rank, principal component analysis (PCA), machine learning priors or another regularization. Regularization may be applied independently for one high resolution volume or jointly across multiple volumes. In this way, the reconstruction can be performed by a forward model that accounts for motion or other variations between low-resolution acquisitions.

The reconstruction may be described as min ∥AMI_{HR}−I_{LR}∥₂²+λ∥I_{HR}∥₂², where I_{LR} represent the low-resolution acquired images, I_{HR} is the target high-resolution volume, M is the estimated motion transform, and λ controls the regularization. A is an encoding matrix that aligns the acquired images based on the acquisition encoding used. For example, if the spatial encodings include rotated views at 0°, 15°, 30°, and so on, A applies a rotation of 0°, 15°, 30°, and so on to align each of the images.

The reconstruction can also be performed in k-space or hybrid space by modeling a 1D, 2D, or 3D Fourier transform in the forward model (e.g., a Fourier transform operator can be included in the encoding matrix A). In this case, I_{LR} and I_{HR} can respectively represent the low- and high-resolution imaging data in the k-space or hybrid domain. Similarly, the estimated motion transform, M, can be represented in hybrid or k-space.

The reconstruction forward model may also include a model of other factors, such as the acquired slice profiles, geometric distortions, effects of the B₀ and B₁ inhomogeneity, and phase variations across low resolution volumes. These factors can be modeled and included in the A encoding matrix. For example, slice profiles can be estimated based on RF pulses and measured B₀ and B₁ inhomogeneity and incorporated into A matrix. The reconstruction model may also be extended to model other image artifacts or variations between low-resolution volumes, such as eddy-current related magnitude and phase variations and motion-related intensity changes due to a change of distance to receiver coils.

Acceleration technique may be used to sample fewer low-resolution or spatially encoded volumes (e.g., a subset of the rotation angles or spatial encodings) to generate a high-resolution volume. Different accelerated reconstruction may be used to generate one or more high resolution images from the subset of the encoded volumes. For example, the high-resolution images can be reconstructed from undersampled encoded volumes (e.g., only a portion of rotation angles or spatial encodings) by adding additional constraints in the model-based reconstruction, such as low-rank or wavelet constraints. In some implementations, data from different repetitions or contrast encodings (e.g., diffusion encoding directions), may be combined to jointly reconstruct the high-resolution data, increasing the number of encoded volumes and improving reconstruction conditioning. Any number of encoded volumes can be combined to generate the high-resolution images.

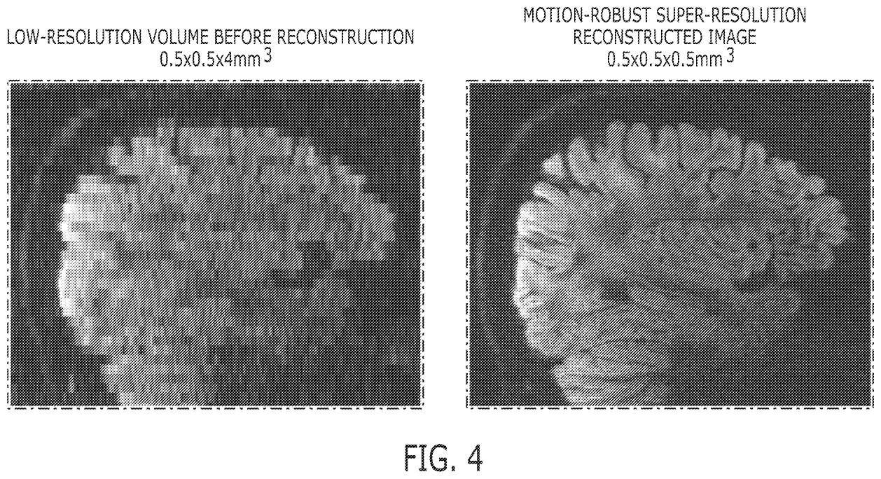

FIG. 4 provides an example of MRI data before and after applying the motion-aware model-based super-resolution reconstruction, which included slice profile modeling in the present example. Axial images were acquired with a 0.5×0.5×4 mm³ resolution and the reconstruction was applied to improve the resolution to 0.5×0.5×0.5 mm³.

Referring again to FIG. 1A, high-resolution images can be generated in block 110. For example, the generated images may have a reduced slice thickness compared to the acquired images. The images generated in block 110 can be further processed for the desired application. For example, the diffusion-weighted images generated may be processed to produce fractional anisotropy (FA) maps, T₂* maps, quantitative maps, segmentation, or other types of images.

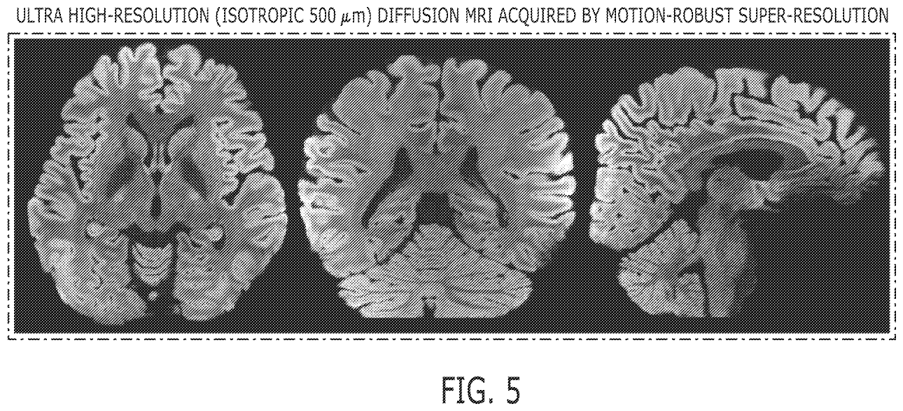

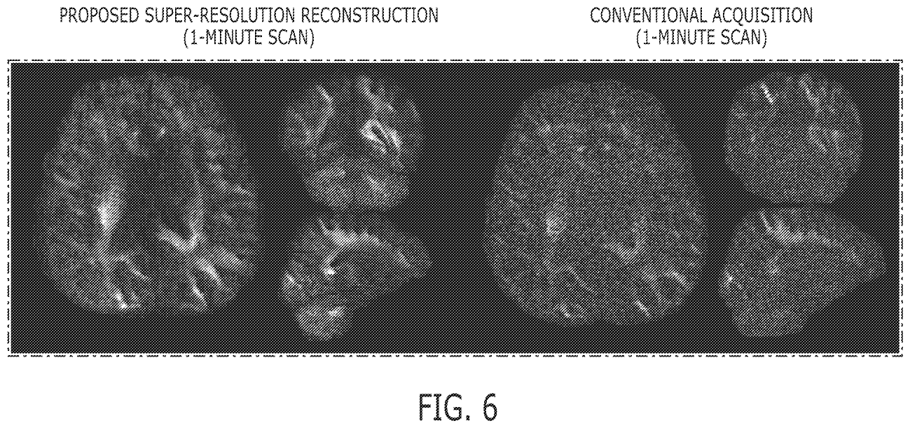

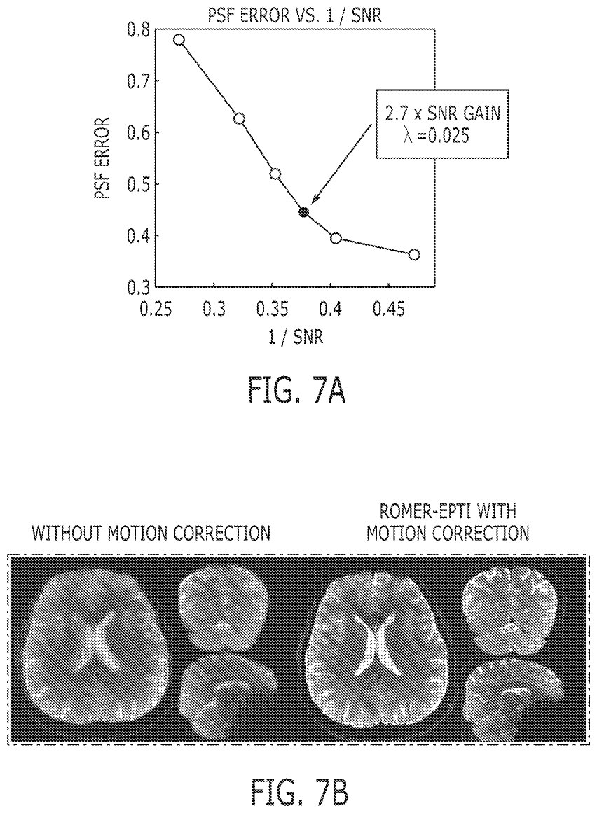

An example of generated high-resolution diffusion-weighted images is provided in FIG. 5. This example shows that process 100 can recover high spatial resolution information. An additional example of mean diffusion images is shown in FIG. 6. The example images were acquired in a scan time of 1 minute and achieved significantly higher image SNR over conventional acquisition in a diffusion imaging scan.

Referring now to FIGS. 2A and 2B, an example MRI data acquisition strategy is illustrated, which may be used to sample each low-resolution or spatial-encoded volume. In this example, the use of distortion-free or distortion-reduction acquisition reduces geometric distortion differences across the low resolution or spatially-encoded volumes, providing robustness to field changes due to motion, field drift, or eddy currents and increasing the reconstruction accuracy when combing the encoded volumes in the proposed super resolution system. For example, the MRI data may be acquired using a reduced-distortion or distortion-free acquisition, such as multi-shot or single-shot ACE-EPTI or EPTI acquisition. Such methods can provide multi-contrast images with reduced or mitigated distortion and blurring by sampling in the hybrid k-t domain where the signal evolution and phase accumulation that typically cause distortion and blurring in conventional methods are addressed.

ACE-EPTI minimizes the TE for a spin-echo acquisition by minimizing deadtime between the 90° and 180° pulses and beginning the readout at the spin-echo point, which provides additional SNR gain. ACE-EPTI also uses self-navigated encoding trajectories as illustrated in FIG. 2B that can estimate inter-shot variations, such as motion and phase variations. Further details of ACE-EPTI are provided in Dong, Zijing et al. “SNR-efficient distortion-free diffusion relaxometry imaging using accelerated echo-train shifted echo-planar time-resolving imaging (ACE-EPTI).” Magnetic Resonance in Medicine 88.1 (2022): 164-179, which is incorporated herein by reference in its entirety. Other distortion-free or distortion-reduction strategies can also be used, such as multi-shot EPI, segmented EPI, parallel imaging, PSF-EPI, titled CAIPI, TSE or GRE, and blip-up and blip-down EPI. In some implementations, non-cartesian sampling (e.g., spiral, radial, periodically rotated overlapping parallel lines with enhanced reconstruction (PROPELLER), or circular) can be implemented to sample the k-t domain or be combined with other distortion reduction strategies to acquire the low resolution or spatially-encoded super-resolution volumes.

An example pulse sequence diagram is provided in FIG. 2A. A spin-echo (SE) may be produced at a time TE_{SE} using a 90° excitation radiofrequency pulse (RF) followed by an inversion or 180° RF pulse at a time TE_{SE}/2. Optional diffusion gradients can be included, for example as a pair of gradients symmetrically placed on either side of the inversion pulse. The slice selection gradients may be selected to acquire images at different slice orientations or rotations angles as illustrated in FIG. 1C. While FIG. 2A illustrated an example diffusion-weighted pulse sequence diagram, the pulse sequence may be modified for other desired contrasts, encodings, and so on.

To maximize or increase SNR, the readout can begin at the spin echo at TE_{SE}, which may improve SNR by 30-40% in some configurations, for example. The readout can be configured to sample a hybrid space called “k-t” space throughout the echo train. For example, the hybrid space can represent the phase-encoding k-space line (k_{y}) sampled at time (t). Magnetic gradients, Gₓ and G_{y}, can be applied along x and y spatial dimensions, respectively. Gₓ gradients can be alternatingly applied to form a readout line in k-space at each prescribed k_{y} position, and G_{y} gradient blips can be applied between readouts to sample k_{y}-t space in a desired pattern. For 3D or SMS imaging, G_{z} gradients can also be played along z to sample in the kₓ-k_{y}-k_{z}-t space. For example, FIG. 2B provides two non-limiting example patterns of k_{y}-t sampling achieved using a 5-shot acquisition and a 3-shot acquisition combined with k-t partial Fourier. In both examples, the k-space center is sampled in every shot to provide self-navigation. The hybrid space can be sampled in any number of shots. For example, single-shot acquisition can be used to provide high robustness to phase variations caused by the use of high b-values or strong diffusion gradients. In other implementations, non-Cartesian sampling (e.g., spiral, radial, PROPELLER, or circular sampling) can be used to sample k-space or the hybrid space. In some embodiments, partial Fourier or other strategies, such as elliptic centric filling, can be used to reduce the k-space or hybrid space coverage or reduce TE.

The readout may fully sample k-t space or may use undersampled k-t space to reduce scan time. When undersampling is used, the reconstruction may use compact kernels to interpolate under-sampled k-t space to generate fully-sampled k-space. Other reconstruction strategies can also be used, including subspace reconstruction, compressed sensing, low-rank reconstruction, and so forth. The acquisition may include measuring a low-resolution calibration scan for use with under-sampling interpolation. Other interpolation methods may also be used to fill in under-sample k-t space.

### Examples

### Introduction

As a non-limiting example implementation, ROtating-view Motion-robust supEr Resolution Echo Planar Time-resolved Imaging method (Romer-EPTI) technique can be implemented to achieve in-vivo high-resolution dMRI and microstructure imaging. The technique uses a rotating-view super-resolution acquisition with an ACE-EPTI acquisition. The Romer-EPTI can achieve an overall 5× SNR gain (RomerxΣPTI=3.8×1.3), while providing images with high motion robustness, minimized artifacts, and completely-free from distortions that enable improved super-resolution reconstruction and high effective resolution. In Romer-EPTI, thick-slice acquisition at different slice angles combined with simultaneous multi-slice excitation is used to provide SNR efficiency gain of ˜3.8 fold. Each thick-slice volume of a different slice angle is acquired using an accelerated echo-train shifted EPTI (ACE-EPTI) acquisition to achieve minimal TE (39 ms) and optimized readout length, providing an additional 30-40% SNR gain over conventional echo-planar imaging (EPI). Such strategy provides multi-echo images free from distortion and blurring by resolving signal evolutions across the readout. Eliminating spatial blurring along phase-encoding (PE) can help preserve spatial resolution compared to conventional methods. For example, in conventional EPI, there can be >30% of blurring at 500 μm resolution even when using in-plane acceleration of R=4. Eliminating the distortion can not only preserve spatial resolution, but also improve super-resolution reconstruction by having consistent geometry across thick-slab volumes when there is subject motion or B₀ field change. The thick-slice volumes acquired at different angles will then be used to reconstruct the high-resolution volume. The Romer acquisition scheme was designed to avoid spin-history artifacts. Inter-shot and inter-volume phase variation was corrected in the proposed approach using the acquired center k-space for self-navigation. The example Romer-reconstruction framework incorporates motion correction and slice profiles between thick-slice volumes into the reconstruction model for high motion robustness. dMRI data were acquired at 500 μm isotropic resolution in-vivo using Romer-EPTI at 3 T and 485 μm isotropic resolution at 7 T with high image quality that revealed detailed fibers in gray matter. Romer-EPTI was also applied to microstructure imaging to examine the time-dependency diffusion property of the human brain.

### Methods

Each thick-slice volume was first acquired using an ACE-EPTI acquisition to achieve distortion-free imaging at 500 μm with self-navigated physiological motion correction (FIG. 2B, using the center of k-space). The echo-train shifted readout started at the spin-echo with minimized TE (TE_{SE}=39 ms at 500 μm, b=1000 s/mm²), which can provide ˜30% SNR gain over EPI at 0.86-mm resolution. A phase-corrected subspace reconstruction was employed to recover multi-echo images across the EPTI readout. Then, thick-slice volumes were acquired at different slice orientations (rotated around the anterior-posterior axis, PE). FIG. 3 illustrates the designed Romer acquisition framework. First, different diffusion directions were acquired for each slice orientation to avoid spin-history artifacts. To recover high-resolution volume for a given super-resolution factor (SR_{factor}), N low-resolution rotating volumes can be acquired, where N≥π/2×SR_{factor} based on the Nyquist-sampling theorem. Therefore, we acquired N=12 angles for an SR_{factor} of 8 to achieve 500 μm isotropic dMRI with a 15° increment, that can offer 2.7× SNR gain (3.8× SNR efficiency gain when combined with SMS=2) (FIG. 3). The microstructure imaging was acquired using Romer with single-shot EPTI for high robustness to phase variations at 2 mm isotropic resolution.

A motion-corrected super-resolution reconstruction was used to recover high-resolution volumes. The reconstruction was performed using an optimization: min ∥AMI_{HR}−I_{LR}∥₂²+λ∥I_{HR}∥₂², where I_{LR} represent the low-resolution images, I_{HR} is the target high-resolution volume, M is the rigid-motion transform, A is an encoding matrix constructed based on 90°-180° slice profiles, and λ controls the Tikhonov regularization. Complex data were used in the reconstruction, and phase variations were removed to obtain real value diffusion MRI data for reduced noise floor.

In vivo dMRI data were acquired in the brain using Romer-EPTI on a 3 T Siemens Prisma and a 7T Siemens Terra scanner with a 32-channel coil. The 3T data were acquired with 500 μm isotropic resolution and 25 diffusion directions. Imaging parameters include: SR_{factor}=8, Nₒᵣᵢₑₙₜₐₜᵢₒₙ=12, Nₛₕₒₜ=5, SMS=2, b-value=1000 s/mm², echo-spacing=1.54 ms, TE_{range}=39-136 ms (64 echoes), TR=3.1 s. The 7 T data were acquired at 485 isotropic resolution. k-t partial Fourier was used to reduce the acquisition shots. Imaging parameters include: SR_{factor}=8, Nₒᵣᵢₑₙₜₐₜᵢₒₙ=12, Nₛₕₒₜ=3, SMS=2, partial Fourier=5/8, b-value=1000 s/mm², TE_{SE}=41, and TR=3.1 s.

### Results

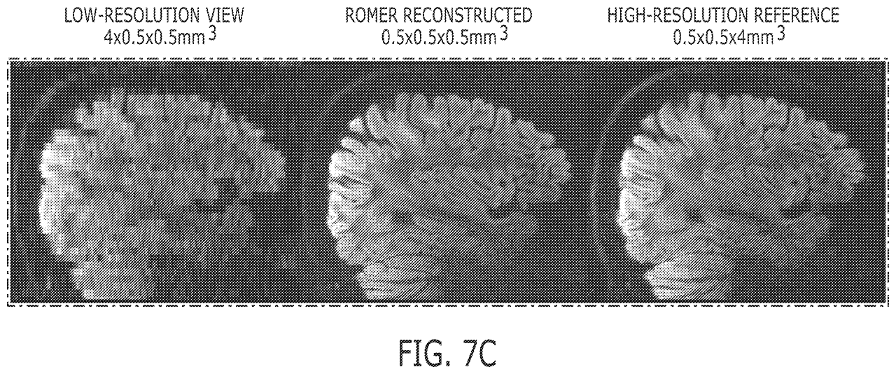

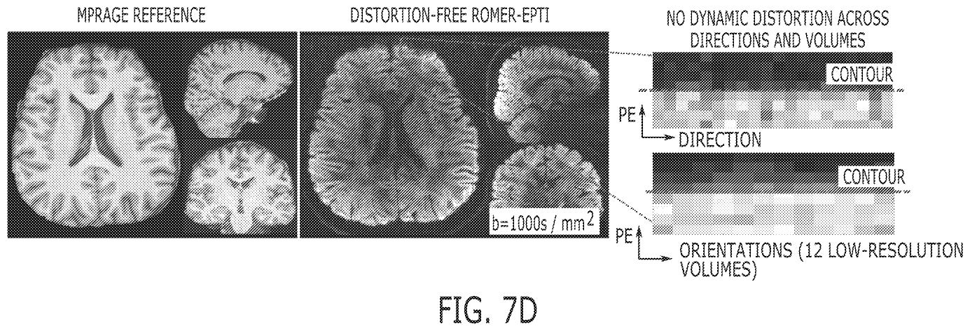

FIG. 5 shows the diffusion MRI data acquired by Romer-EPTI at a mesoscale level (500 μm isotropic resolution) in three orthogonal views. A was chosen as 0.025 based on the PSFₑᵣᵣₒᵣ VS. 1/SNR L-curve, as shown in FIG. 7A, for an SNR gain of 2.7× with moderate errors (corresponding to ˜14% side-lobe). FIG. 6 shows the high SNR gain provided by Romer-EPTI at a high b-value compared to a conventional EPI method. Single-shot sampling was used in Romer-EPTI for high robustness to phase variations at high b-values. FIG. 7B shows the comparison of image quality for in-vivo imaging in the presence of subject motion with and without the use of the presently described motion-aware super resolution method. The Romer method provides sharp and high-quality images even in the presence of subject motion during the scan. FIG. 7C shows reconstructed Romer-EPTI images. The Romer method recovered the high spatial resolution at 500 μm isotropic resolution without resolution loss compared to the actual acquired high in-plane resolution view of the image. As shown in FIG. 7D, the distortion-free high-resolution diffusion-weighted images (DWI) show the same geometry as the MPRAGE reference. No eddy-current or motion-induced dynamic distortion was observed across the low-resolution volumes or diffusion directions, as shown in FIG. 7D, demonstrating the distortion-free capability of Romer-EPTI.

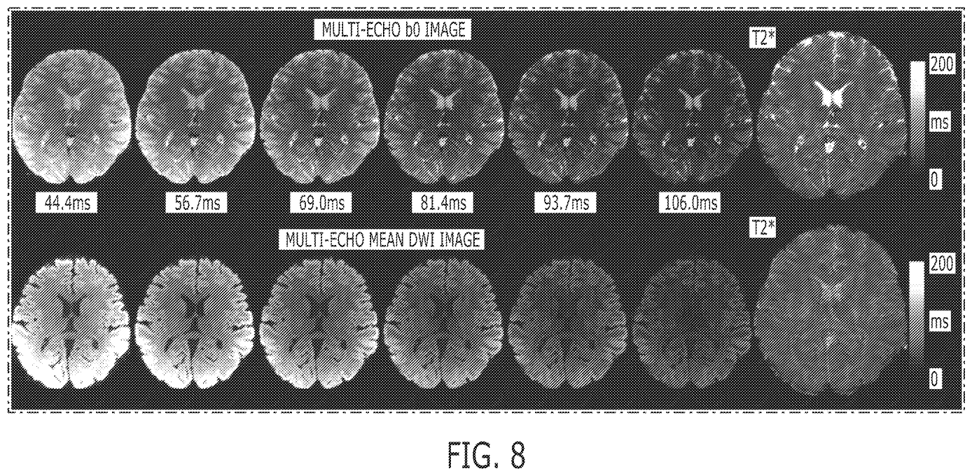

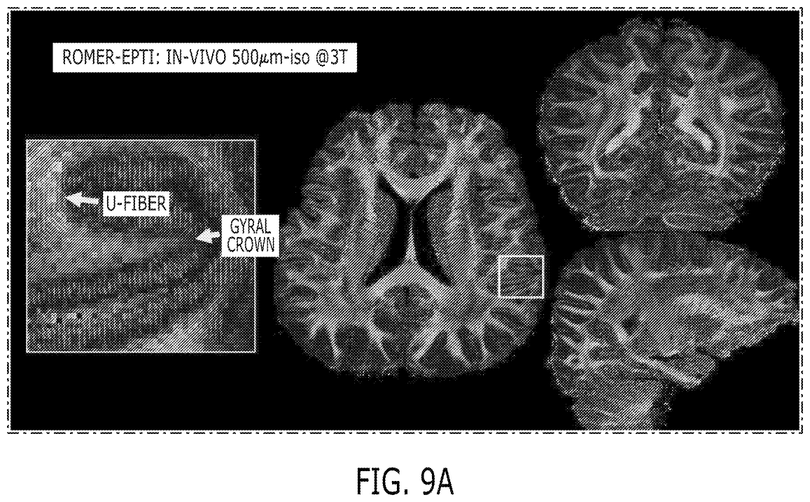

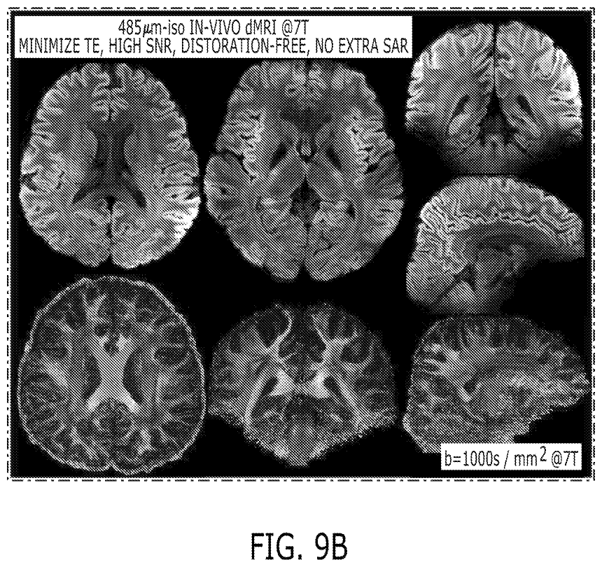

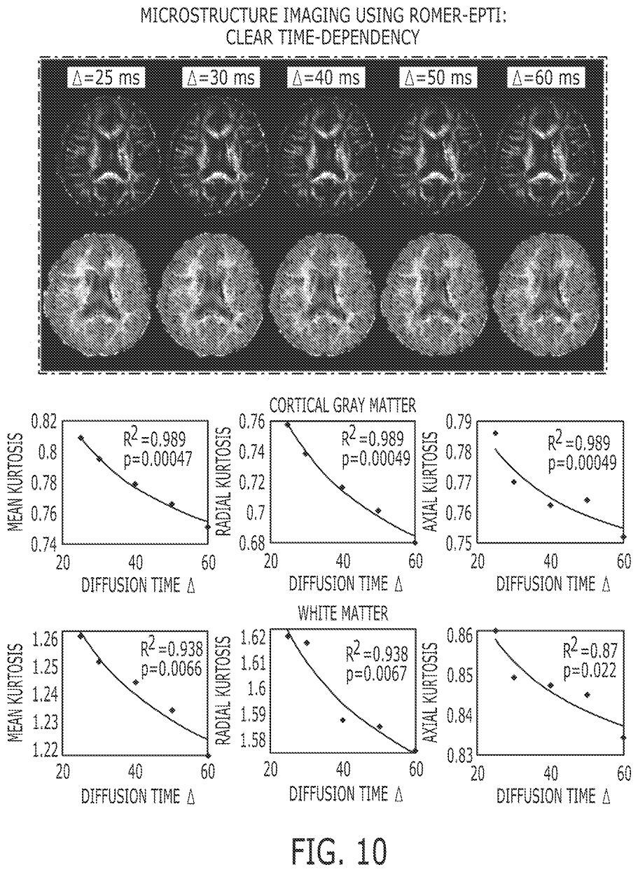

FIG. 8 shows the high image quality of the mean non-DWI and DWI data together with the averaged fitted T₂* maps at 500 μm isotropic resolution. Lower values are observed in the DW-T₂′ images due to suppression of extracellular waters with diffusion encoding. The corresponding colored fractional anisotropy (FA) maps and tensor results are shown in FIG. 9A. Using Romer-EPTI, high-quality tensors were obtained and revealed clear U-fibers and fibers in the gyral crowns and walls. FIG. 9B shows 485 μm-isotropic dMRI data acquired at 7 T using Romer-EPTI. The low SAR and short TE provided by Romer-EPTI make it suitable for ultra-high field MRI and further SNR improvements at higher field strength. The results demonstrate the high image quality and high resolution for 7 T diffusion imaging achieved by Romer-EPTI. FIG. 10 shows the microstructure imaging results acquired using Romer-EPTI. The diffusion metrics shown were estimated from Romer-EPTI data acquired with different diffusion times in a short scan time. Clear time-dependency in cortical gray matter and in white matter were both observed in the acquired high-SNR data.

### Conclusion

Romer-EPTI achieves significantly higher SNR efficiency while providing distortion-free imaging with minimized motion and spin-history artifacts. It enables efficient mesoscale dMRI at both 3 T and 7 T, and can be useful for probing microstructure with significantly improved acquisition speed, image quality and cost-effectiveness.

### System

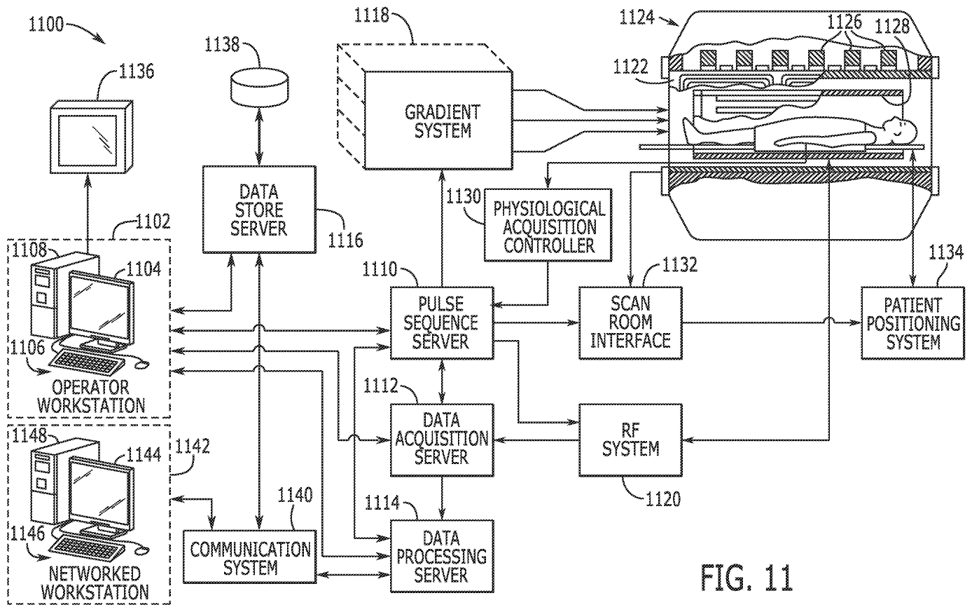

Referring particularly now to FIG. 11, an example of an MRI system 1100 that can implement the methods described herein is illustrated. The MRI system 1100 includes an operator workstation 1102 that may include a display 1104, one or more input devices 1106 (e.g., a keyboard, a mouse), and a processor 1108. The processor 1108 may include a commercially available programmable machine running a commercially available operating system. The operator workstation 1102 provides an operator interface that facilitates entering scan parameters into the MRI system 1100. The operator workstation 1102 may be coupled to different servers, including, for example, a pulse sequence server 1110, a data acquisition server 1112, a data processing server 1114, and a data store server 1116. The operator workstation 1102 and the servers 1110, 1112, 1114, and 1116 may be connected via a communication system 1140, which may include wired or wireless network connections.

The MRI system 1100 also includes a magnet assembly 1124 that includes a polarizing magnet 1126, which may be a low-field magnet. The MRI system 1100 may optionally include a whole-body RF coil 1128 and a gradient system 1118 that controls a gradient coil assembly 1122.

The pulse sequence server 1110 functions in response to instructions provided by the operator workstation 1102 to operate a gradient system 1118 and a radiofrequency (“RF”) system 1120. Gradient waveforms for performing a prescribed scan are produced and applied to the gradient system 1118, which then excited gradient coils in an assembly 1122 to produce the magnetic field gradients (e.g., Gₓ, G_{y}, and G_{z}) that can be used for spatially encoding magnetic resonance signals. The gradient coil assembly 1122 forms part of a magnet assembly 1124 that includes a polarizing magnet 1126 and a whole-body RF coil 1128.

RF waveforms are applied by the RF system 1120 to the RF coil 1128, or a separate local coil to perform the prescribed magnetic resonance pulse sequence. Responsive magnetic resonance signals detected by the RF coil 1128, or a separate local coil, are received by the RF system 1120. The responsive magnetic resonance signals may be amplified, demodulated, filtered, and digitized under direction of commands produced by the pulse sequence server 1110. The RF system 1120 includes an RF transmitter for producing a wide variety of RF pulses used in MRI pulse sequences. The RF transmitter is responsive to the prescribed scan and direction from the pulse sequence server 1110 to produce RF pulses of the desired frequency, phase, and pulse amplitude waveform. The generated RF pulses may be applied to the whole-body RF coil 1128 or to one or more local coils or coil arrays.

The RF system 1120 also includes one or more RF receiver channels. An RF receiver channel includes an RF preamplifier that amplifies the magnetic resonance signal received by the coil 1128 to which it is connected, and a detector that detects and digitizes the/and Q quadrature components of the received magnetic resonance signal. The magnitude of the received magnetic resonance signal may, therefore, be determined at a sampled point by the square root of the sum of the squares of the I and Q components:

$$M = \sqrt{( {I}^{2} + {Q}^{2} )}$$

and the phase of the received magnetic resonance signal may also be determined according to the following relationship:

$$ϕ = {tan}^{- 1} ( \frac{Q}{I} )$$

The pulse sequence server 1110 may receive patient data from a physiological acquisition controller 1130. By way of example, the physiological acquisition controller 1130 may receive signals from a number of different sensors connected to the patient, including electrocardiogram (“ECG”) signals from electrodes, or respiratory signals from a respiratory bellows or other respiratory monitoring devices. These signals may be used by the pulse sequence server 1110 to synchronize, or “gate,” the performance of the scan with the subject's heartbeat or respiration.

The pulse sequence server 1110 may also connect to a scan room interface circuit 1132 that receives signals from various sensors associated with the condition of the patient and the magnet system. Through the scan room interface circuit 1132, a patient positioning system 1134 can receive commands to move the patient to desired positions during the scan.

The digitized magnetic resonance signal samples produced by the RF system 1120 are received by the data acquisition server 1112. The data acquisition server 1112 operates in response to instructions downloaded from the operator workstation 1102 to receive the real-time magnetic resonance data and provide buffer storage, so that data are not lost by data overrun. In some scans, the data acquisition server 1112 passes the acquired magnetic resonance data to the data processor server 1114. In scans that require information derived from acquired magnetic resonance data to control the further performance of the scan, the data acquisition server 1112 may be programmed to produce such information and convey it to the pulse sequence server 1110. For example, during pre-scans, magnetic resonance data may be acquired and used to calibrate the pulse sequence performed by the pulse sequence server 1110. As another example, navigator signals may be acquired and used to adjust the operating parameters of the RF system 1120 or the gradient system 1118, or to control the view order in which k-space is sampled. In still another example, the data acquisition server 1112 may also process magnetic resonance signals used to detect the arrival of a contrast agent in a magnetic resonance angiography (“MRA”) scan. For example, the data acquisition server 1112 may acquire magnetic resonance data and processes it in real-time to produce information that is used to control the scan.

The data processing server 1114 receives magnetic resonance data from the data acquisition server 1112 and processes the magnetic resonance data in accordance with instructions provided by the operator workstation 1102. Such processing may include, for example, reconstructing two-dimensional or three-dimensional images by performing a Fourier transformation of raw k-space data, performing other image reconstruction algorithms (e.g., iterative or backprojection reconstruction algorithms), applying filters to raw k-space data or to reconstructed images, generating functional magnetic resonance images, or calculating motion or flow images.

Images reconstructed by the data processing server 1114 are conveyed back to the operator workstation 1102 for storage. Real-time images may be stored in a data base memory cache, from which they may be output to operator display 1102 or a display 1136. Batch mode images or selected real time images may be stored in a host database on disc storage 1138. When such images have been reconstructed and transferred to storage, the data processing server 1114 may notify the data store server 1116 on the operator workstation 1102. The operator workstation 1102 may be used by an operator to archive the images, produce films, or send the images via a network to other facilities.

The MRI system 1100 may also include one or more networked workstations 1142. For example, a networked workstation 1142 may include a display 1144, one or more input devices 1146 (e.g., a keyboard, a mouse), and a processor 1148. The networked workstation 1142 may be located within the same facility as the operator workstation 1102, or in a different facility, such as a different healthcare institution or clinic.

The networked workstation 1142 may gain remote access to the data processing server 1114 or data store server 1116 via the communication system 1140. Accordingly, multiple networked workstations 1142 may have access to the data processing server 1114 and the data store server 1116. In this manner, magnetic resonance data, reconstructed images, or other data may be exchanged between the data processing server 1114 or the data store server 1116 and the networked workstations 1142, such that the data or images may be remotely processed by a networked workstation 1142.

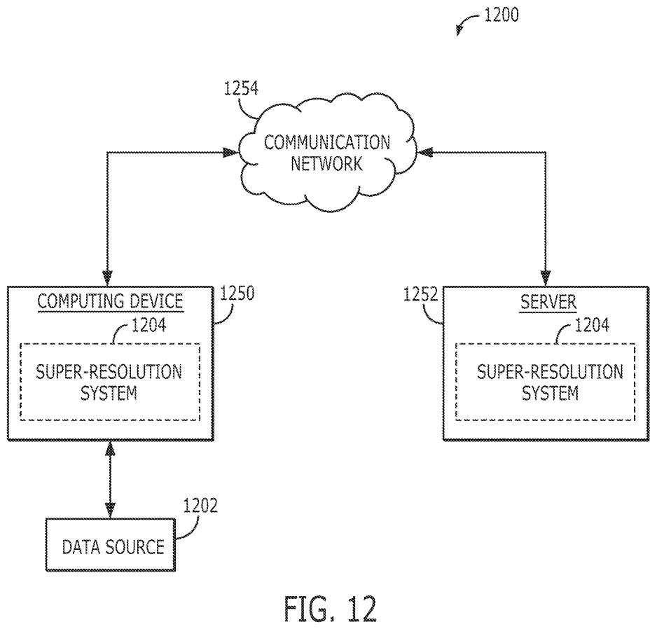

Referring now to FIG. 12, an example of an MRI system 1200 is shown, which may be used in accordance with some aspects of the systems and methods described in the present disclosure. As shown in FIG. 12, a computing device 1250 can receive one or more types of data (e.g., signal evolution data, k-space data, receiver coil sensitivity data) from data source 1202. In some configurations, computing device 1250 can execute at least a portion of a super-resolution system 1204 to reconstruct images from magnetic resonance data (e.g., k-space data) acquired using a super-resolution technique. In some configurations, the super-resolution system 1204 can implement an automated pipeline to provide MRI images with high resolution and SNR, such as fMRI images, diffusion images, anatomical images, etc.

Additionally or alternatively, in some configurations, the computing device 1250 can communicate information about data received from the data source 1202 to a server 1252 over a communication network 1254, which can execute at least a portion of the super-resolution system 1204. In such configurations, the server 1252 can return information to the computing device 1250 (and/or any other suitable computing device) indicative of an output of the super-resolution system 1204.

In some configurations, computing device 1250 and/or server 1252 can be any suitable computing device or combination of devices, such as a desktop computer, a laptop computer, a smartphone, a tablet computer, a wearable computer, a server computer, a virtual machine being executed by a physical computing device, and so on. The computing device 1250 and/or server 1252 can also reconstruct images from the data.

In some configurations, data source 1202 can be any suitable source of data (e.g., measurement data, images reconstructed from measurement data, processed image data), such as an MRI system, another computing device (e.g., a server storing measurement data, images reconstructed from measurement data, processed image data), and so on. In some configurations, data source 1202 can be local to computing device 1250. For example, data source 1202 can be incorporated with computing device 1250 (e.g., computing device 1250 can be configured as part of a device for measuring, recording, estimating, acquiring, or otherwise collecting or storing data). As another example, data source 1202 can be connected to computing device 1250 by a cable, a direct wireless link, and so on. Additionally or alternatively, in some configurations, data source 1202 can be located locally and/or remotely from computing device 1250, and can communicate data to computing device 1250 (and/or server 1252) via a communication network (e.g., communication network 1254).

In some configurations, communication network 1254 can be any suitable communication network or combination of communication networks. For example, communication network 1254 can include a Wi-Fi network (which can include one or more wireless routers, one or more switches, etc.), a peer-to-peer network (e.g., a Bluetooth network), a cellular network (e.g., a 3G network, a 4G network, etc., complying with any suitable standard, such as CDMA, GSM, LTE, LTE Advanced, WiMAX, etc.), other types of wireless network, a wired network, and so on. In some configurations, communication network 1254 can be a local area network, a wide area network, a public network (e.g., the Internet), a private or semi-private network (e.g., a corporate or university intranet), any other suitable type of network, or any suitable combination of networks. Communications links shown in FIG. 12 can each be any suitable communications link or combination of communications links, such as wired links, fiber optic links, Wi-Fi links, Bluetooth links, cellular links, and so on.

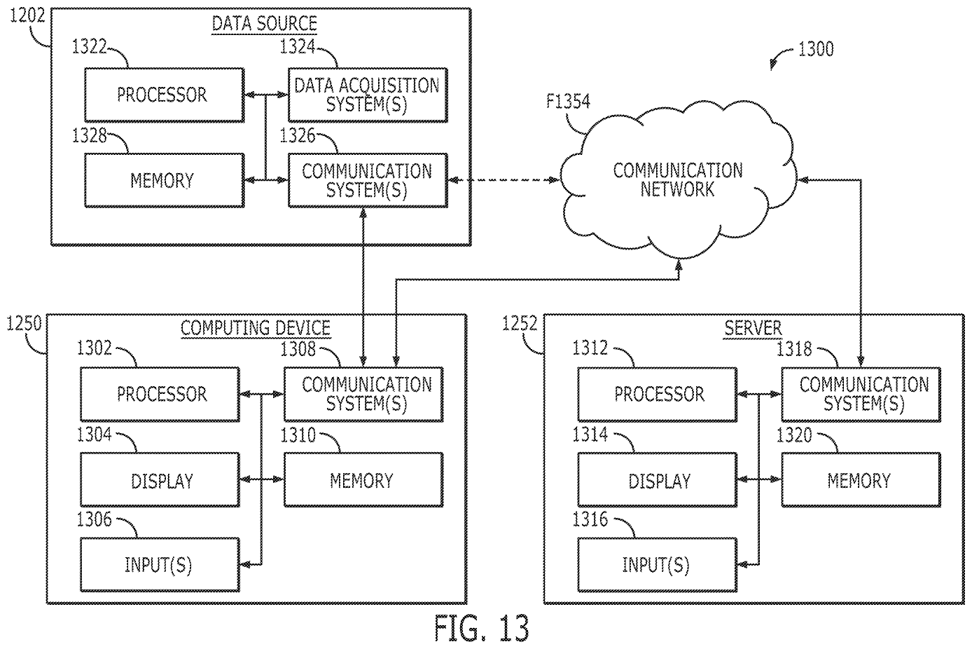

Referring now to FIG. 13, an example of hardware 1300 that can be used to implement data source 1202, computing device 1250, and server 1252 in accordance with some configurations of the systems and methods described in the present disclosure is shown.

As shown in FIG. 13, in some configurations, computing device 1250 can include a processor 1302, a display 1304, one or more inputs 1306, one or more communication systems 1308, and/or memory 1310. In some configurations, processor 1302 can be any suitable hardware processor or combination of processors, such as a central processing unit (“CPU”), a graphics processing unit (“GPU”), and so on. In some configurations, display 1304 can include any suitable display devices, such as a liquid crystal display (“LCD”) screen, a light-emitting diode (“LED”) display, an organic LED (“OLED”) display, an electrophoretic display (e.g., an “e-ink” display), a computer monitor, a touchscreen, a television, and so on. In some configurations, inputs 1306 can include any suitable input devices and/or sensors that can be used to receive user input, such as a keyboard, a mouse, a touchscreen, a microphone, and so on.

In some configurations, communications systems 1308 can include any suitable hardware, firmware, and/or software for communicating information over communication network 1254 and/or any other suitable communication networks. For example, communications systems 1308 can include one or more transceivers, one or more communication chips and/or chip sets, and so on. In a more particular example, communications systems 1308 can include hardware, firmware, and/or software that can be used to establish a Wi-Fi connection, a Bluetooth connection, a cellular connection, an Ethernet connection, and so on.

In some configurations, memory 1310 can include any suitable storage device or devices that can be used to store instructions, values, data, or the like, that can be used, for example, by processor 1302 to present content using display 1304, to communicate with server 1252 via communications system(s) 1308, and so on. Memory 1310 can include any suitable volatile memory, non-volatile memory, storage, or any suitable combination thereof. For example, memory 1310 can include random-access memory (“RAM”), read-only memory (“ROM”), electrically programmable ROM (“EPROM”), electrically erasable ROM (“EEPROM”), other forms of volatile memory, other forms of non-volatile memory, one or more forms of semi-volatile memory, one or more flash drives, one or more hard disks, one or more solid state drives, one or more optical drives, and so on. In some configurations, memory 1310 can have encoded thereon, or otherwise stored therein, a computer program for controlling operation of computing device 1250. In such configurations, processor 1302 can execute at least a portion of the computer program to present content (e.g., images, user interfaces, graphics, tables), receive content from server 1252, transmit information to server 1252, and so on. For example, the processor 1302 and the memory 1310 can be configured to perform the methods described herein.

In some configurations, server 1252 can include a processor 1312, a display 1314, one or more inputs 1316, one or more communications systems 1318, and/or memory 1320. In some configurations, processor 1312 can be any suitable hardware processor or combination of processors, such as a CPU, a GPU, and so on. In some configurations, display 1314 can include any suitable display devices, such as an LCD screen, LED display, OLED display, electrophoretic display, a computer monitor, a touchscreen, a television, and so on. In some configurations, inputs 1316 can include any suitable input devices and/or sensors that can be used to receive user input, such as a keyboard, a mouse, a touchscreen, a microphone, and so on.

In some configurations, communications systems 1318 can include any suitable hardware, firmware, and/or software for communicating information over communication network 1254 and/or any other suitable communication networks. For example, communications systems 1318 can include one or more transceivers, one or more communication chips and/or chip sets, and so on. In a more particular example, communications systems 1318 can include hardware, firmware, and/or software that can be used to establish a Wi-Fi connection, a Bluetooth connection, a cellular connection, an Ethernet connection, and so on.

In some configurations, memory 1320 can include any suitable storage device or devices that can be used to store instructions, values, data, or the like, that can be used, for example, by processor 1312 to present content using display 1314, to communicate with one or more computing devices 1250, and so on. Memory 1320 can include any suitable volatile memory, non-volatile memory, storage, or any suitable combination thereof. For example, memory 1320 can include RAM, ROM, EPROM, EEPROM, other types of volatile memory, other types of non-volatile memory, one or more types of semi-volatile memory, one or more flash drives, one or more hard disks, one or more solid state drives, one or more optical drives, and so on. In some configurations, memory 1320 can have encoded thereon a server program for controlling operation of server 1252. In such configurations, processor 1312 can execute at least a portion of the server program to transmit information and/or content (e.g., data, images, a user interface) to one or more computing devices 1250, receive information and/or content from one or more computing devices 1250, receive instructions from one or more devices (e.g., a personal computer, a laptop computer, a tablet computer, a smartphone), and so on.

In some configurations, the server 1252 is configured to perform the methods described in the present disclosure. For example, the processor 1312 and memory 1320 can be configured to perform the methods described herein.

In some configurations, data source 1202 can include a processor 1322, one or more data acquisition systems 1324, one or more communications systems 1326, and/or memory 1328. In some configurations, processor 1322 can be any suitable hardware processor or combination of processors, such as a CPU, a GPU, and so on. In some configurations, the one or more data acquisition systems 1324 are generally configured to acquire data, images, or both, and can include an MRI system. Additionally or alternatively, in some configurations, the one or more data acquisition systems 1324 can include any suitable hardware, firmware, and/or software for coupling to and/or controlling operations of an MRI system. In some configurations, one or more portions of the data acquisition system(s) 1324 can be removable and/or replaceable.

Note that, although not shown, data source 1202 can include any suitable inputs and/or outputs. For example, data source 1202 can include input devices and/or sensors that can be used to receive user input, such as a keyboard, a mouse, a touchscreen, a microphone, a trackpad, a trackball, and so on. As another example, data source 1202 can include any suitable display devices, such as an LCD screen, an LED display, an OLED display, an electrophoretic display, a computer monitor, a touchscreen, a television, etc., one or more speakers, and so on.

In some configurations, communications systems 1326 can include any suitable hardware, firmware, and/or software for communicating information to computing device 1250 (and, in some configurations, over communication network 1254 and/or any other suitable communication networks). For example, communications systems 1326 can include one or more transceivers, one or more communication chips and/or chip sets, and so on. In a more particular example, communications systems 1326 can include hardware, firmware, and/or software that can be used to establish a wired connection using any suitable port and/or communication standard (e.g., VGA, DVI video, USB, RS-232, etc.), Wi-Fi connection, a Bluetooth connection, a cellular connection, an Ethernet connection, and so on.

In some configurations, memory 1328 can include any suitable storage device or devices that can be used to store instructions, values, data, or the like, that can be used, for example, by processor 1322 to control the one or more data acquisition systems 1324, and/or receive data from the one or more data acquisition systems 1324; to generate images from data; present content (e.g., data, images, a user interface) using a display; communicate with one or more computing devices 1250; and so on. Memory 1328 can include any suitable volatile memory, non-volatile memory, storage, or any suitable combination thereof. For example, memory 1328 can include RAM, ROM, EPROM, EEPROM, other types of volatile memory, other types of non-volatile memory, one or more types of semi-volatile memory, one or more flash drives, one or more hard disks, one or more solid state drives, one or more optical drives, and so on. In some configurations, memory 1328 can have encoded thereon, or otherwise stored therein, a program for controlling operation of medical image data source 1202. In such configurations, processor 1322 can execute at least a portion of the program to generate images, transmit information and/or content (e.g., data, images, a user interface) to one or more computing devices 1250, receive information and/or content from one or more computing devices 1250, receive instructions from one or more devices (e.g., a personal computer, a laptop computer, a tablet computer, a smartphone, etc.), and so on.

In some configurations, any suitable computer-readable media can be used for storing instructions for performing the functions and/or processes described herein. For example, in some configurations, computer-readable media can be transitory or non-transitory. For example, non-transitory computer-readable media can include media such as magnetic media (e.g., hard disks, floppy disks), optical media (e.g., compact discs, digital video discs, Blu-ray discs), semiconductor media (e.g., RAM, flash memory, EPROM, EEPROM), any suitable media that is not fleeting or devoid of any semblance of permanence during transmission, and/or any suitable tangible media. As another example, transitory computer-readable media can include signals on networks, in wires, conductors, optical fibers, circuits, or any suitable media that is fleeting and devoid of any semblance of permanence during transmission, and/or any suitable intangible media.

As used herein in the context of computer implementation, unless otherwise specified or limited, the terms “component,” “system,” “module,” “controller,” “framework,” and the like are intended to encompass part or all of computer-related systems that include hardware, software, a combination of hardware and software, or software in execution. For example, a component may be, but is not limited to being, a processor device, a process being executed (or executable) by a processor device, an object, an executable, a thread of execution, a computer program, or a computer. By way of illustration, both an application running on a computer and the computer can be a component. One or more components (or system, module, and so on) may reside within a process or thread of execution, may be localized on one computer, may be distributed between two or more computers or other processor devices, or may be included within another component (or system, module, and so on).

In some implementations, devices or systems disclosed herein can be utilized or installed using methods embodying aspects of the disclosure. Correspondingly, description herein of particular features, capabilities, or intended purposes of a device or system is generally intended to inherently include disclosure of a method of using such features for the intended purposes, a method of implementing such capabilities, and a method of installing disclosed (or otherwise known) components to support these purposes or capabilities. Similarly, unless otherwise indicated or limited, discussion herein of any method of manufacturing or using a particular device or system, including installing the device or system, is intended to inherently include disclosure, as embodiments of the disclosure, of the utilized features and implemented capabilities of such device or system.

As used herein, the phrase “at least one of A, B, and C” means at least one of A, at least one of B, and/or at least one of C, or any one of A, B, or C or combination of A, B, or C. A, B, and C are elements of a list, and A, B, and C may be anything contained in the Specification.

The present disclosure has described one or more preferred embodiments, and it should be appreciated that many equivalents, alternatives, variations, and modifications, aside from those expressly stated, are possible and within the scope of the invention.

1. A magnetic resonance imaging (MRI) system comprising:
a magnet system configured to generate a static polarizing magnetic field (B₀) about at least a portion of a subject arranged in the MRI system;
a plurality of gradient coils configured to apply magnetic gradients to the polarizing magnetic field;
a radio frequency (RF) system configured to apply an excitation field to the subject;
a computer system programmed to carry out steps comprising:
(a) control the plurality of gradient coils and RF system to acquire a first set of imaging data from the subject at a first sampling resolution using a first spatial encoding and a first sampling pattern;
(b) control the plurality of gradient coils and RF system to acquire another set of imaging data from the subject using another spatial encoding that differs from a preceding spatial encoding and another sampling pattern;
(c) repeat step (b) for a plurality of repetitions to generate a plurality of sets of imaging data, each of the plurality of sets of imaging data having a respective sampling pattern;
(d) estimate motion between the plurality of sets of imaging data to determine a motion transformation that represents motion of the subject between the plurality of sets of imaging data;
(e) using the motion transformation, perform a model-based super-resolution reconstruction of the plurality of sets of imaging data to generate an image of the subject having a resolution greater than the first resolution.

2. The system of claim 1, wherein the computer system is further programmed to apply distortion correction to each of the plurality of sets of imaging data prior to performing the model-based super-resolution reconstruction.

3. The system of claim 1, wherein the computer system is further programmed to perform a reduced-distortion method to acquire first set of imaging data.

4. The system of claim 3, wherein the reduced-distortion method comprises echo-planar time-resolved imaging process.

5. The system of claim 3, wherein the reduced-distortion method comprises an accelerated echo-train shifted echo-planar time-resolved imaging process.

6. The system of claim 1, wherein the plurality of data sets is acquired from a slice within a slice direction in the subject and the another sampling pattern comprises a pattern of sampling rotated around an axis orthogonal to slice direction compared to the first sampling pattern.

7. The system of claim 1, wherein the first set of imaging data comprises a plurality of images acquired with a plurality of contrast encodings, and wherein each of the plurality of sets of imaging data comprises a plurality of images acquired with the plurality of contrast encodings.

8. The system of claim 1, wherein controlling the plurality of gradient coils and RF system comprises performing simultaneous multi-slice imaging.

9. The system of claim 1, wherein the model-based super-resolution reconstruction comprises solving a regularized optimization to reduce a regularization term and a difference between a target imaging data and each of the plurality of sets of imaging data, wherein the target imaging data is a high-resolution image transformed by the motion transformation and an encoding matrix formed from spatial encoding across the plurality of imaging data.

10. The system of claim 9, wherein the regularized optimization is defined by
$$min {‖ {AMI}_{H R} - {I}_{L R} ‖}_{2}^{2} + λ {‖ {I}_{H R} ‖}_{2}^{2} ,$$
where A is the encoding matrix, M is the motion transformation, I_{HR} is the high-resolution image, I_{LR} is the plurality sets of imaging data, and λ controls a level of regularization.

11. The system of claim 9, wherein the regularization term provides at least one of a Tikhonov regularization, a wavelet regularization, or a low-rank regularization.

12. A method for generating magnetic resonance imaging (MRI) images of a subject, the method comprising the steps of:
(a) accessing a plurality of MRI imaging data sets of the subject having a first resolution, wherein each of the plurality of MRI imaging data sets was acquired with a selected sampling pattern;
(b) estimating motion between the plurality of MRI imaging data sets to determine a motion transformation corresponding to motion of the subject between the plurality of MRI imaging data sets;
(c) applying a model-based super-resolution reconstruction to the plurality of MRI imaging data sets, wherein the reconstruction accounts for the motion transformation, and wherein the reconstruction generates an image of the subject corresponding to an image volume with a second resolution greater than the first resolution.

13. The method of claim 12, further comprising applying distortion correction prior to applying the model-based reconstruction.

14. The method of claim 12, wherein the MRI imaging data sets were acquired with a reduced-distortion acquisition method.

15. The method of claim 12, wherein the MRI imaging data sets were acquired with an echo-planar time-resolved imaging method.

16. The method of claim 12, wherein the MRI imaging data sets were acquired with an accelerated echo-train shifted echo-planar time-resolved imaging method.

17. The method of claim 12, wherein the sampling patterns of the plurality of MRI imaging data sets comprise rotated slice positions.

18. The method of claim 12, wherein the model-based reconstruction comprises solving a regularized optimization to reduce a difference between a first imaging data set and a second imaging data set and a regularization, wherein the first imaging data set corresponds to a target high-resolution image that is transformed by the motion transformation and an encoding matrix corresponding to the sampling patterns and the second imaging data set corresponds to acquired low-resolution images.

19. The method of claim 18, wherein the regularized optimization is defined by
$$min {‖ {AMI}_{H R} - {I}_{L R} ‖}_{2}^{2} + λ {‖ {I}_{H R} ‖}_{2}^{2} ,$$
where A is an encoding matrix that represents the sampling patterns, M represents the motion transformation, I_{HR} represents target high-resolution imaging data that corresponds to the image volume with the second resolution, I_{LR} represents the plurality of MRI imaging data sets with the first resolution, and λ controls a level of regularization.

20. The method of claim 18, wherein the regularization comprises at least one of a Tikhonov regularization, a wavelet regularization, or a low-rank regularization.

21. The method of claim 12, wherein the model-based reconstruction further accounts for magnitude and phase variations between each of the plurality of MRI imaging data sets.

22. The method of claim 12, further comprising modeling slice profiles of the plurality of MRI imaging data sets to generate estimated slice profiles, and wherein the reconstruction accounts for the estimated slice profiles.

23. The method of claim 12, wherein each of the plurality of MRI imaging data sets comprise a group of imaging data, wherein each of the group of imaging data is characterized by one of a plurality of contrast weightings, and wherein the reconstruction is jointly applied to the group of imaging data.
